(19) United States
(12) Patent Application Publication
(10) Pub. No.: US 2023/0207280 A1
(43) Pub. Date: Jun. 29, 2023

(54) SUBSTRATE TREATING APPARATUS

(71) Applicant: SEMES CO., LTD., Cheonan-si (KR)

(72) Inventors: Sun Joo PARK, Seoul (KR); Kyung Seok MIN, Suwon-si (KR); Hyun Jong SHIM, Seongnam-si (KR); Sun Wook JUNG, Hwaseong-si (KR); Sang Min MUN, Cheonan-si (KR); Ho Joong SUN, Suwon-si (KR)

(73) Assignee: SEMES CO., LTD., Cheonan-si (KR)

(21) Appl. No.: 18/147,381

(22) Filed: Dec. 28, 2022

(30) Foreign Application Priority Data
Dec. 29, 2021 (KR) 10-2021-0191292
Jun. 15, 2022 (KR) 10-2022-0072732

(51) Int. Cl. H01J 37/32

(52) U.S. Cl. CPC H01J 37/32568; H01J 2237/0262; H01J 2237/334

(57) ABSTRACT

Disclosed is a substrate treating apparatus. The substrate treating apparatus includes a housing having a treatment space, in which a substrate is treated, a support unit that supports the substrate in the treatment space, a shower plate having a through-hole, through which a process gas flows to the treatment space, a plasma source that excites plasma by exciting the process gas supplied to the treatment space, and a density adjusting member that adjusts a density of the plasma generated in the treatment space by changing a dielectric permittivity, and the density adjusting member is located on the shower plate.

### CROSS-REFERENCE TO RELATED APPLICATIONS

A claim for priority under 35 U.S.C. § 119 is made to Korean Patent Application Nos. 10-2021-0191292 and 10-2022-0072732 filed on Dec. 29, 2021 and Jun. 15, 2022, in the Korean Intellectual Property Office, the entire contents of which are hereby incorporated by reference.

### BACKGROUND

Embodiments of the inventive concept described herein relate to a substrate treating apparatus, and more particularly, to an apparatus for plasma-treating a substrate.

Plasma refers to an ionized gaseous state including ions, radicals, and electrons. The plasma is generated by very high temperature, strong electric fields, or radio frequency (RF) electromagnetic fields. A semiconductor device manufacturing process may include an etching process of removing a thin film formed on a substrate, such as a wafer, by using plasma. The etching process is performed as ions and/or radicals of plasma collide with a thin film on a substrate or react with a thin film.

For example, when an etching process is performed by using plasma, thin films formed in some of all of areas of a substrate are etched more excessively than in a process requirement condition, and thin films formed in other areas are etched less than in the process requirement condition. That is, a difference between the etching rates for the areas of the substrate occurs when the substrate is treated by using plasma. A difference between the etching rates for the areas of the substrate occurs due to various factors, such as flows of gases in the treatment space, a uniformity of the supplied process gas in the treatment space, a location of the supplied process gas, and a uniformity of the plasma in the treatment space, and the factors cause a difference between the densities or intensities of the plasma for areas of the treatment space, in which the substrate is plasma-treated. When the density or intensity of the plasma in the treatment space becomes different for the areas, the plasma of different conditions is applied for the areas of the substrate. Accordingly, when the substrate is treated by using the plasma, it is difficult to uniformly treat all the areas of the substrate.

### SUMMARY

Embodiments of the inventive concept provide a substrate treating apparatus that may uniformly treat a substrate.

Embodiments of the inventive concept also provide a substrate treating apparatus that may efficiently adjust intensities of electric fields generated for areas of a treatment space.

Embodiments of the inventive concept also provide a substrate treating apparatus that may treat a substrate with plasma having a uniform density by adjusting an intensity of an electric field generated in a treatment space.

The aspect of the inventive concept is not limited thereto, and other unmentioned aspects of the present invention may be clearly appreciated by those skilled in the art from the following descriptions.

The inventive concept provides a substrate treating apparatus. The substrate treating apparatus includes a housing having a treatment space, in which a substrate is treated, a support unit that supports the substrate in the treatment space, a shower plate having a through-hole, through which a process gas flows to the treatment space, a plasma source that excites plasma by exciting the process gas supplied to the treatment space, and a density adjusting member that adjusts a density of the plasma generated in the treatment space by changing a dielectric permittivity, and the density adjusting member is located on the shower plate.

According to an embodiment, the plasma source may include an electrode plate located on an upper side of the shower plate, and the density adjusting member may be disposed between the shower plate and the electrode plate.

According to an embodiment, the density adjusting member may include a plurality of dielectric pads, and the plurality of dielectric pads may be spaced apart from each other while having different permittivities.

According to an embodiment, the through-hole may be located in a space between the plurality of spaced dielectric pads.

According to an embodiment, the dielectric pad may include a center pad and an edge pad, the center pad may have a first dielectric permittivity, and is located in a circular center area including a center of the shower plate, and the edge pad may have a second dielectric permittivity, and is located in a ring-shaped edge area that surrounds the center area.

According to an embodiment, the first dielectric permittivity may be higher than the second dielectric permittivity.

According to an embodiment, the first dielectric permittivity may be lower than or equal to the second dielectric permittivity.

According to an embodiment, the dielectric pad may include a plurality of center pads and a plurality of edge pads, the plurality of center pads may be spaced apart from the center area, and the plurality of edge pads may be spaced apart from the edge area.

According to an embodiment, the plurality of center pads may have different dielectric permittivities, and the plurality of edge pads may have different dielectric permittivities.

According to an embodiment, the dielectric pad may be located in any one of a center area including a center of the shower plate, a middle area that surrounds the center area, and an edge area that surround the middle area.

According to an embodiment, the density adjusting member may contact an upper area of the shower plate.

According to an embodiment, the electrode plate may be grounded or a high-frequency electric power may be applied thereto.

The inventive concept provides a substrate treating apparatus. The substrate treating apparatus includes a housing defining a treatment space, in which a substrate is treated, a support unit that supports the substrate in the treatment space, a gas supply unit that supplies a process gas, a plasma source that excites the process gas supplied into the treatment space by generating an electric field in the treatment space, and a density adjusting member that differently adjusts a density of plasma generated by exciting the process gas according to areas of the treatment space, by shielding the electric field generated in the treatment space.

According to an embodiment, the density adjusting member may include at least one dielectric pad, and the dielectric pad may shield the electric field generated in at least any one of a center area including a center of the treatment space, a middle area that surrounds the center area, and an edge area that surround the middle area, when viewed from a top.

According to an embodiment, the dielectric pad may include a center pad, a middle pad, and an edge pad, the center pad may have a first dielectric permittivity, and shields an electric field of the center area, the middle pad may have a second dielectric permittivity, and shields an electric field of the middle area, and the edge pad may have a third dielectric permittivity, and shields an electric field of the edge area.

According to an embodiment, the first dielectric permittivity, the second dielectric permittivity, and the third dielectric permittivity may be different.

According to an embodiment, the first dielectric permittivity may be higher than the second dielectric permittivity and the third dielectric permittivity, and the second dielectric permittivity may be higher than the third dielectric permittivity.

According to an embodiment, a plurality of center pads may be disposed in the center area, a plurality of middle pads may be disposed in the middle area, a rein a plurality of edge pads may be disposed in the edge area, and the center pads, the middle pads, or the edge pads may have different dielectric permittivities.

The inventive concept provides a substrate treating apparatus. The substrate treating apparatus includes a housing having a treatment space, in which a substrate is treated, a support unit that supports the substrate in the treatment space, a gas supply unit that supplies a process gas, a shower plate having a through-hole, through which a process gas flows to the treatment space, an electrode plate disposed on an upper side of the shower plate, and being grounded or to which high-frequency electric power is applied, a lower electrode disposed in an interior of the support unit, and being grounded or to which the high-frequency electric power is applied, and a density adjusting member located between the shower plate and the electrode plate, and that adjusts a density of plasma generated in the treatment space by shielding an electric field generated in the treatment space by the electrode plate and the lower electrode, the density adjusting member includes a plurality of dielectric pads, the plurality of dielectric pads have different dielectric permittivities, and are spaced apart at the upper side of the shower plate, and the through-hole is located in a space between the plurality of spaced dielectric pads.

According to an embodiment, the dielectric pad may include at least one center pad and at least one edge pad, the center pad may have a first dielectric permittivity, and is located in a circular center area including a center of the shower plate, the edge pad may have a second dielectric permittivity, and is located in a ring-shaped edge area that surrounds the center area, and the first dielectric permittivity may be higher than the second dielectric permittivity.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view schematically illustrating a substrate treating apparatus according to an embodiment of the inventive concept;

FIG. 2 is a view schematically illustrating a process chamber according to an embodiment of FIG. 1;

FIG. 3 is a view schematically illustrating a state of a density adjusting member according to an embodiment of FIG. 2, when viewed from a top;

FIG. 4 is a view schematically illustrating a state, in which plasma is generated in a treatment space by the density adjusting member of FIG. 3;

FIG. 5 is a view schematically illustrating a state of a density adjusting member according to another embodiment of FIG. 2, when viewed from a top;

FIG. 6 is a view of a state, in which a density of plasma is formed differently according to areas of a substrate by the density adjusting member of FIG. 5, when viewed from a top;

FIG. 7 is a view schematically illustrating a modification of the density adjusting member of FIG. 5;

FIG. 8 is a view schematically illustrating a state of a density adjusting member according to another embodiment of FIG. 2, when viewed from a top;

FIG. 9 is a view schematically illustrating a state, in which plasma is generated in a treatment space by the density adjusting member of FIG. 8; and

FIG. 10 is a view schematically illustrating a modification of the density adjusting member of FIG. 8.

### DETAILED DESCRIPTION

Hereinafter, exemplary embodiments of the inventive concept will be described in more detail with reference to the accompanying drawings. The embodiments of the inventive concept may be modified in various forms, and the scope of the inventive concept should not be construed to be limited due to the following embodiments. The embodiments of the inventive concept are provided to describe the inventive concept for those skilled in the art more completely. Accordingly, the shapes and the like of the components in the drawings are exaggerated to emphasize clearer descriptions.

The terms such as first and second may be used to describe various components, but the components are not limited to the terms. The terms may be used only for the purpose of distinguishing one component from another component. For example, while not deviating from the scope of the inventive concept, a first component may be named a second component, and similarly, the second component may be named the first component.

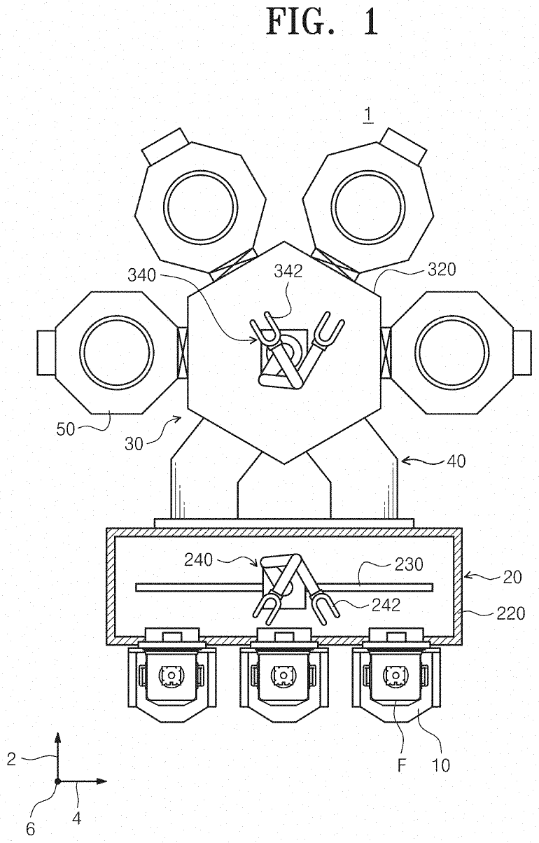

Hereinafter, embodiments of the inventive concept will be described with reference to FIGS. 1 to 10.

FIG. 1 is a view schematically illustrating a substrate treating apparatus according to an embodiment of the inventive concept. Referring to FIG. 1, a substrate treating apparatus 1 according to an embodiment of the inventive concept may include a load port 10, a normal pressure feeding module 20, a vacuum feeding module 30, a load lock chamber 40, and a process chamber 50.

The load port 10 may be disposed on one side of the normal pressure feeding module 20, which will be described below. At least one load port 10 may be disposed on one side of the normal pressure feeding module 20. The number of load ports 10 may increase or decrease according to a condition, such as a process efficiency or a footprint.

A container “F” may be positioned on the load port 10. The container “F” may be loaded on or unloaded from the load port 10 by a feeding means (not illustrated), such as an overhead transfer apparatus (OHT), an overhead conveyor, or an automatic guided vehicle, or an operator. The container “F” may include various kinds of containers according to kinds of the received articles. The container “F” may be a closed container such as a front open unified pod (FOUP).

The normal pressure feeding module 20 and the vacuum feeding module 30 may be disposed along a first direction 2. Hereinafter, a direction that is perpendicular to the first direction 2 when viewed from the top is defined as a second direction 4. Furthermore, a direction that is perpendicular to the first direction 2 and the second direction 4 is defined as a third direction 6. The third direction 6 may refer to a direction that is perpendicular to a ground surface.

The normal pressure feeding module 20 may transfer a substrate “W” between the container “F” and the load lock chamber 40, which will be described below. According to an embodiment, the normal pressure feeding module 20 may extract the substrate “W” from the container “F” and transfer it to the load lock chamber 40, or may extract the substrate “W” from the load lock chamber 40 and transfer it into an interior of the container “F”.

The normal pressure feeding module 20 may include a transfer frame 220 and a first transfer robot 240. The transfer frame 220 may be disposed between the load port 10 and the load lock chamber 40. The load port 10 may be connected to the transfer frame 220. An internal atmosphere of the transfer frame 220 may be maintained at a normal pressure. According to an embodiment, an interior of the transfer frame 220 may be created by an atmospheric pressure atmosphere.

A transfer rail 230 is disposed in the transfer frame 220. A lengthwise direction of the transfer rail 230 may be parallel to a lengthwise direction of the transfer frame 220. The first transfer robot 240 may be located on the transfer rail 230.

The first transfer robot 240 may transfer the substrate “W” between the container “F” seated on the load port 10 and the load lock chamber 40, which will be described below. The first transfer robot 240 may be moved forwards and rearwards in the second direction 4 along the transfer rail 230. The first transfer robot 240 may be moved in a perpendicular direction (for example, the third direction 6). The first transfer robot 240 has a first transfer hand 242 that is moved forwards and rearwards, or rotated on a horizontal surface. The substrate “W” is positioned on the first transfer hand 242. The first transfer robot 240 may have a plurality of first transfer hands 242. The plurality of first transfer hands 242 may be disposed to be spaced apart from each other in an upward/downward direction.

The vacuum feeding module 30 may be disposed between the load lock chamber 40, which will be described below, and the process chamber 50. The vacuum feeding module 30 may include a transfer chamber 320 and a second transfer robot 340.

An internal atmosphere of the transfer chamber 320 may be maintained at a vacuum pressure. The second transfer robot 340 may be provided in the transfer chamber 320. For example, the second transfer robot 340 may be disposed at a central portion of the transfer chamber 320. The second transfer robot 340 transfers the substrate “W” between the load lock chamber 40, which will be described below, and the process chamber 50. Furthermore, the second transfer robot 340 may transfer the substrate “W” between the process chambers 50.

The second transfer robot 340 may be moved in a perpendicular direction (for example, the third direction 6). The second transfer robot 340 has a second transfer hand 342 that is moved forwards and rearwards, or rotated on a horizontal surface. The substrate “W” is positioned on the second transfer hand 342. The second transfer robot 340 may have a plurality of second transfer hands 342. The plurality of second transfer hands 342 may be disposed to be spaced apart from each other along an upward/downward direction.

At least one process chamber 50 may be connected to the transfer chamber 320, which will be described below. According to an embodiment, the transfer chamber 320 may have a polygonal shape. The load lock chamber 40, which will be described below, and the process chamber 50 may be disposed at a circumference of the transfer chamber 320. For example, as illustrated in FIG. 1, the transfer chamber 320 having a hexagonal shape may be disposed at a central portion of the vacuum feeding module 30, and the load lock chamber 40 and the process chamber 50 may be disposed at a circumference thereof. Unlike the above description, the shape of the transfer chamber 320 and the number of process chambers 50 may be variously changed according to a requirement condition of a user or a process requirement condition.

The load lock chamber 40 may be disposed between the transfer frame 220 and the transfer chamber 320. The load lock chamber 40 may have a buffer space, in which the substrate “W” is replaced, between the transfer frame 220 and the transfer chamber 320. For example, the substrate “W”, on which a specific treatment has been made in the process chamber 50, may temporarily stay in the buffer space of the load lock chamber 40. Furthermore, the substrate “W”, which is extracted from the container “F” such that a specific treatment is scheduled to be made thereon, may temporarily stay in the buffer space of the load lock chamber 40.

As described above, the internal atmosphere of the transfer frame 220 may be maintained at an atmospheric pressure, and the internal atmosphere of the transfer chamber 320 may be maintained at a vacuum pressure. Accordingly, the load lock chamber 40 may be disposed between the transfer frame 220 and the transfer chamber 320, and an internal atmosphere thereof may be switched between the atmospheric pressure and the vacuum pressure.

The process chamber 50 is connected to the transfer chamber 320. A plurality of process chambers 50 may be provided. The process chamber 50 may be a chamber that performs a specific process on the substrate “W”. According to an embodiment, the substrate “W” may be treated by using plasma. For example, the process chamber 50 may be a chamber that performs an etching process of removing a thin film on the substrate “W” by using plasma, an ashing process of removing a photoresist layer, a deposition process of forming a thin film on the substrate “W”, a dry cleaning process, an atomic layer deposition process of depositing an atomic layer on the substrate, or an atomic layer etching process of etching an atomic layer on the substrate. However, the present disclosure is not limited thereto, and a plasma treatment process performed in the process chamber 50 may be variously modified to known plasma treatment processes.

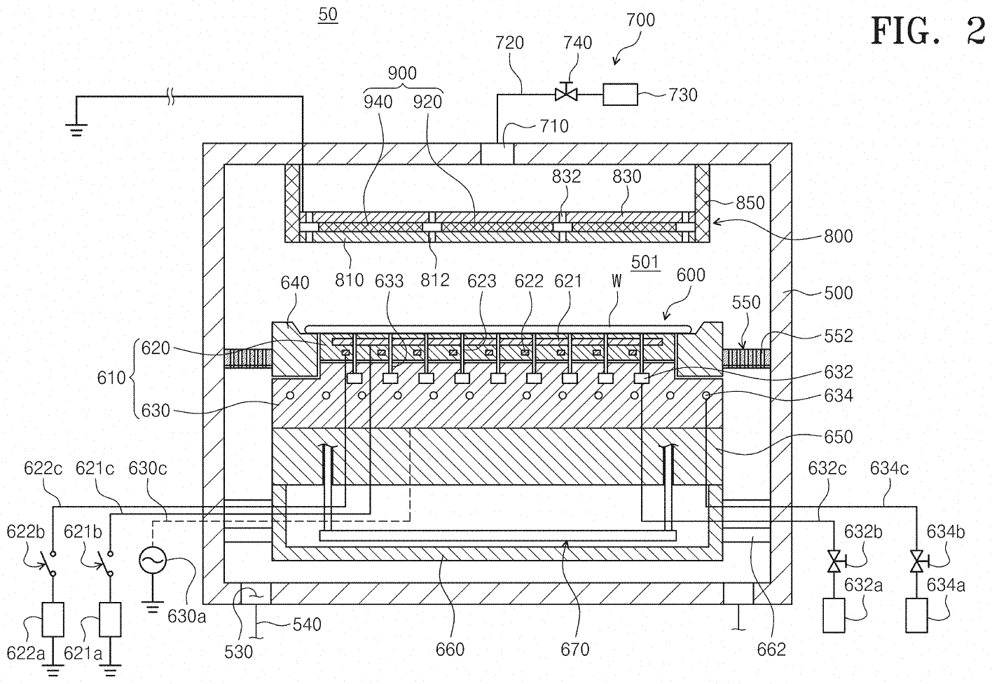

FIG. 2 is a view schematically illustrating the process chamber according to the embodiment of FIG. 1. Referring to FIG. 2, the process chamber 50 according to the embodiment may treat the substrate “W” with plasma. The process chamber 50 may include a housing 500, a support unit 600, a gas supply unit 700, a shower head unit 800, and a density adjusting member 900.

The housing 500 may have a shape, an interior of which is closed. The housing 500 has a treatment space 501, in which the substrate “W” is treated, in the interior thereof. The treatment space 501 may be maintained at a vacuum atmosphere as a whole while the substrate “W” is treated. A material of the housing 500 may include a metal. According to an embodiment, the material of the housing 500 may include aluminum. The housing 500 may be grounded.

A carrying-in hole (not illustrated) may be formed on one side wall of the housing 500. The carrying-in hole (not illustrated) functions as a space, through which the substrate “W” is carried into or out of the treatment space 501. The carrying-in hole (not illustrated) may be selectively opened and closed by a door assembly that is not illustrated.

An exhaust hole 530 may be formed on a bottom surface of the housing 500. An exhaust line 540 is connected to the exhaust hole 530. A pressure reducing member that is not illustrated may be installed in the exhaust line 540. The pressure reducing member (not illustrated) may be any one of known pumps that provide a negative pressure. The process gas, process impurities, and the like supplied into the treatment space 501 may be discharged from the treatment space 501 sequentially via the exhaust hole 530 and the exhaust line 540. Furthermore, because the pressure reducing member (not illustrated) provides the negative pressure, the pressure of the treatment space 501 may be adjusted.

An exhaust baffle 550 that functions to allow the treatment space 501 to be exhausted more uniformly may be disposed on an upper side of the exhaust hole 530. The exhaust baffle 550 may be located between a side wall of the housing 500 and the support unit 600, which will be described below. The exhaust baffle 550 may have a substantially ring shape when viewed from the top. At least one baffle hole 552 may be formed in the exhaust baffle 550. The baffle hole 552 may pass through an upper surface and a lower surface of the exhaust baffle 550. The process gas, the process impurities, and the like of the treatment space 501 may flow to the exhaust hole 530 and the exhaust line 540 through the baffle hole 552.

The support unit 600 is disposed in the interior of the housing 500. The support unit 600 may be disposed in the treatment space 501. The support unit 600 may be disposed to be spaced apart from a bottom surface to an upper side of the housing 500 by a specific distance. The support unit 600 supports the substrate “W”. The support unit 600 may include an electrostatic chuck that suctions the substrate “W” by using an electrostatic force. Unlike this, the support unit 600 may support the substrate “W” by using various schemes, such as vacuum adsorption or mechanical clamping. Hereinafter, the support unit 600 including the electrostatic chuck will be described as an example.

The support unit 600 may include an electrostatic chuck 610, an insulation plate 650, and a lower cover 660.

The electrostatic chuck 610 supports the substrate “W”. The electrostatic chuck 610 may include a dielectric plate 620 and a base plate 630. The dielectric plate 620 is located at an upper end of the support unit 600. The dielectric plate 620 may be formed of a dielectric substance and may have a disk shape. The substrate “W” is positioned on the upper surface of the dielectric plate 620. According to an embodiment, the upper surface of the dielectric plate 620 may have a radius that is smaller than that of the substrate “W”. When the substrate “W” is positioned on the upper surface of the dielectric plate 620, a peripheral area of the substrate “W” may be located outside the dielectric plate 620.

An electrode 621 and a heater 622 are disposed in the inner dielectric plate 620. According to an embodiment, the electrode 621 may be located on an upper side of the heater 622 in the interior of the dielectric plate 620. The electrode 621 is electrically connected to a first power source 621a. The first power source 621a may include a DC power source. A first switch 621b is installed between the electrode 621 and the first power source 621a. When the first switch 621b is switched on, the electrode 621 is electrically connected to the first power source 621a and a direct current flows in the electrode 621. An electrostatic force is applied between the electrode 621 and the substrate “W” by a current that flows in the electrode 621. Accordingly, the substrate “W” is absorbed by the dielectric plate 620.

The heater 622 is electrically connected to a second power source 622a. A second switch 622b is installed between the heater 622 and the second power source 622a. When the second switch 622b is switched on, the heater 622 may be electrically connected to the second power source 622a. The heater 622 may generate heat while resisting against a current supplied from the second power source 622a. The heat generated by the heater 622 is delivered to the substrate “W” by a medium of the dielectric plate 620. The substrate “W” positioned on the dielectric plate 620 may be maintained at a specific temperature by the heat generated by the heater 622. The heater 622 may include a spiral coil. Furthermore, the heater 622 may include a plurality of coils. Although not illustrated, the plurality of coils may be provided to different areas of the dielectric plate 620, respectively. For example, a coil that heats a central area of the dielectric plate 620 and a coil that heats a peripheral area thereof may be buried in the dielectric plate 620, and heating degrees of the coils may be independently adjusted. Although it has been described as an example in the above-described example that the heater 622 is located in the interior of the dielectric plate 620, but the inventive concept is not limited thereto. For example, the heater 622 may not be located in the interior of the dielectric plate 620.

At least one first passage 623 may be formed in the interior of the dielectric plate 620. The first passage 623 is formed from an upper surface of the dielectric plate 620 to a bottom of the dielectric plate 620. The first passage 623 is communicated with a second passage 633, which will be described below. The first passage 623 may be formed to be spaced apart at a central area of the dielectric plate 620 and a peripheral area that surrounds the central area when viewed from the top. The first passage 623 functions as a passage, through which a heat transfer medium, which will be described below, is supplied to the bottom surface of the substrate “W”.

The base plate 630 is located below the dielectric plate 620. The base plate 630 may have a disk shape. An upper surface of the base plate 630 may be stepped such that a central area thereof is higher than a peripheral area thereof. A central area of an upper portion of the base plate 630 may have an area corresponding to a bottom surface of the dielectric plate 620. A central area of an upper surface of the base plate 630 may be bonded to a bottom surface of the dielectric plate 620. A ring member 640, which will be described below, may be located on an upper side of a peripheral area of the base plate 630.

The base plate 630 may include a conductive material. For example, a material of the base plate 630 may include aluminum. The base plate 630 may be a metal plate. For example, an entire area of the base plate 630 may be a metal plate. The base plate 630 may be electrically connected to a third power source 630a. The third power source 630a may be a high-frequency power source that generates high-frequency electric power. For example, the high-frequency power source may be an RF power source. The RF power source may be a high bias power RF power source. The base plate 630 receives the high-frequency electric power from the third power source 630a. Accordingly, the base plate 630 may function as an electrode that generates an electric field. According to an embodiment, the base plate 630 may function as a lower electrode of a plasma source, which will be described below. However, the inventive concept is not limited thereto, but the base plate 630 may be grounded to function as the lower electrode.

A first circulation passage 632 and a second circulation passage 634 may be located in an interior of the base plate 630. Furthermore, the second passage 633 may be formed in the interior of the base plate 630.

The first circulation passage 632 may be a passage, through which the heat transfer medium circulates. The first circulation passage 632 may have a spiral shape. The first circulation passage 632 is fluid-communicated with the second passage 633, which will be described below. Furthermore, the first circulation passage 632 is connected to a first supply source 632a through a first supply line 632c.

A heat transfer medium is stored in the first supply source 632a. The heat transfer medium may include an inert gas. According to an embodiment, the heat transfer medium may include a helium (He) gas. However, the inventive concept is not limited thereto, and the heat transfer medium may include various gases or liquids. The heat transfer medium may be a fluid that is supplied to a lower surface of the substrate “W” to solve the unevenness of a temperature of the substrate “W” while the substrate “W” is plasma-treated. Furthermore, the heat transfer medium may function as a medium that transfers the heat transferred from the plasma to the substrate “W”, to the dielectric plate 620 and the ring member 640, which will be described below while the substrate “W” is plasma-treated.

A first valve 632b is installed in the first supply line 632c. The first valve 632b may be an opening/closing valve. The heat transfer medium may be selectively supplied to the first circulation passage 632 as the first valve 632b is opened and closed.

The second passage 633 fluid-communicates the first circulation passage 632 and the first passage 623. The heat transfer medium supplied to the first circulation passage 632 may be supplied to the bottom surface of the substrate “W” sequentially via the second passage 633 and the first passage 623.

The second circulation passage 634 may be a passage, through which a cooling fluid circulates. The second circulation passage 634 may have a spiral shape. Furthermore, the second circulation passage 634 may be disposed such that passages having ring shapes of different radii share the same center. Furthermore, the second circulation passage 634 is connected to a second supply source 634a through a second supply line 634c.

The cooling fluid is stored in the second supply source 634a. For example, the cooling fluid may be cooling water. A cooler that is not illustrated may be provided to the second supply source 634a. The cooler (not illustrated) may cool the cooling fluid to a specific temperature. However, unlike the above-described example, the cooler (not illustrated) may be installed in the second supply line 634c.

A second valve 634b is installed in the second supply line 634c. The second valve 634b may be an opening/closing valve. As the second valve 634b is opened and closed, the cooling fluid may be selectively supplied to the second circulation passage 634. The cooling fluid is supplied to the second circulation passage 634 through the second supply line 634c. The cooling fluid that flows through the second circulation passage 634 may cool the base plate 630. The substrate “W” may be cooled by a medium of the base plate 630.

The ring member 640 is disposed at a peripheral area of the electrostatic chuck 610. According to an example, the ring member 640 may be a focusing ring. The ring member 640 has a ring shape. The ring member 640 is disposed along a circumference of the dielectric plate 620. For example, the ring member 640 may be disposed on an upper side of a peripheral area of the base plate 630.

An upper surface of the ring member 640 may be stepped. According to an embodiment, an inside of the upper surface of the ring member 640 may be located at the same height as that of the upper surface of the dielectric plate 620. Furthermore, an inside of the upper surface of the ring member 640 may support a lower surface of the peripheral area of the substrate “W” located outside the dielectric plate 620. An outside of the upper surface of the ring member 640 may surround a side surface of the peripheral area of the substrate “W”.

The insulation plate 650 is located below the base plate 630. The insulation plate 650 may include an insulation material. The insulation plate 650 electrically insulates the base plate 630 and the lower cover 660, which will be described below. The insulation plate 650 may have a substantially disk shape when viewed from the top. The insulation plate 650 may have an area corresponding to the base plate 630.

The lower cover 660 is located on a lower side of the insulation plate 650. The lower cover 660 may have a cylindrical shape, an upper surface of which is opened, when viewed from the top. The upper surface of the lower cover 660 may be covered by the insulation plate 650. A lift pin assembly 670 that elevates the substrate “W” may be located in an interior space of the lower cover 660.

The lower cover 660 may include a plurality of connecting members 662. The connecting member 662 may connect an outer surface of the lower cover 660 and an inner wall of the housing 500. The plurality of connecting members 662 may be disposed to be spaced apart from each other along a circumferential direction of the lower cover 660. The connecting members 662 support the support unit 600 in the interior of the housing 500. Furthermore, the connecting members 662 may be connected to the housing 500 thus grounded to ground the lower cover 660.

The connecting members 662 may have a hollow shape having a space in an interior thereof. A first power line 621c connected to the first power source 621a, a second power line 622c connected to the second power source 622a, a third power line 630c connected to the third power source 630a, the first supply line 632c connected to the first circulation passage 632, the second supply line 634c connected to the second circulation passage 634, and the like extend to an outside of the housing 500 through a space formed inside the connecting members 662.

The gas supply unit 700 supplies the process gas to the treatment space 501. The gas supply unit 700 may include a gas supply nozzle 710, a gas supply line 720, and a gas supply source 730.

The gas supply nozzle 710 may be installed in a central area of the upper surface of the housing 500. An ejection hole is formed on the bottom surface of the gas supply nozzle 710. The ejection hole (not illustrated) may eject the process gas into the interior of the housing 500.

One end of the gas supply line 720 is connected to the gas supply nozzle 710. An opposite end of the gas supply line 720 is connected to the gas supply source 730. The gas supply source 730 may store the process gas. The process gas may be a gas that is excited into a plasma state by the power source, which will be described below. According to an embodiment, the process gas may include NH₃, NF₃, and/or an inert gas.

A gas valve 740 is installed in the gas supply line 720. The gas valve 740 may be an opening/closing valve. As the gas valve 740 is opened and closed, the process gas may be selectively supplied to the treatment space 501.

The plasma source excites the process gas supplied into the housing 500 into a plasma state. The plasma source according to an embodiment of the inventive concept is capacitively coupled plasma (CCP). However, the inventive concept is not limited thereto, and the process gas supplied to the treatment space 501 may be excited into the plasma state by using inductively coupled plasma (ICP) or microwave plasma. Hereinafter, it will be described as an example that the capacitively coupled plasma (CCP) is used as the plasma source according to an embodiment.

The plasma source may include an upper electrode and a lower electrode. The upper electrode and the lower electrode may be disposed to face each other in the interior of the housing 500. High-frequency electric power may be applied to any one of the electrodes, and the other electrode may be grounded. Unlike this, the high-frequency electric power may be applied to both of the electrodes. An electromagnetic field may be formed in a space between the two electrodes, and the process gas supplied into the space may be excited into a plasma state. A substrate treating process is performed by using the plasma. According to an embodiment, the upper electrode may be an electrode plate 830, which will be described below, and the lower electrode may be the above-described base plate 630.

The shower head unit 800 is located on an upper side of the support unit 600 in the interior of the housing 500. The shower head unit 800 may include a shower plate 810, the electrode plate 830, and a support part 850.

The shower plate 810 is located to face the support unit 600 on an upper side of the support unit 600. The shower plate 810 may be located to be spaced apart from a ceiling surface of the housing 500 downwards. According to an embodiment, the shower plate 810 may have a disk shape having a specific thickness. The shower plate 810 may be an insulator. A plurality of through-holes 812 are formed in the shower plate 810.

The through-holes 812 may pass through an upper surface and a lower surface of the shower plate 810. The through-hole 812 is located to face a hole 832 formed in the electrode plate 830, which will be described below. Furthermore, the through-holes 812 may be located to overlap spaces between dielectric pads 920 and 940, which will be described below, when viewed from the top.

The electrode plate 830 is disposed on an upper side of the shower plate 810. The electrode plate 830 may be disposed to be spaced apart from a ceiling surface to a lower side of the housing 500 by a specific distance. Accordingly, a space may be formed between the electrode plate 830 and the ceiling surface of the housing 500. The electrode plate 830 may have a disk shape having a specific thickness.

A material of the electrode plate 830 may include a metal. The electrode plate 830 may be grounded. However, as described above, the electrode plate 830 may be electrically connected to a high-frequency power source (not illustrated). The bottom surface of the electrode plate 830 may be anodized to minimize generation of an arc by plasma. A cross-section of the electrode plate 830 may have a shape and a cross-sectional area, which are the same as those of the support unit 600.

A plurality of holes 832 are formed in the electrode plate 830. The holes 832 may vertically pass through the upper surface and the lower surface of the electrode plate 830. The plurality of holes 832 correspond to the plurality of through-holes 812 formed in the shower plate 810. Furthermore, the plurality of holes 832 may be located to overlap spaces between the dielectric pads 920 and 940, which will be described below, when viewed from the top. Accordingly, the process gas ejected from the gas supply nozzle 710 may flow to a space formed by combining the electrode plate 830 and the housing 500. The process gas may be supplied to the treatment space 501 via the holes 832 and the through-holes 812.

The support part 850 supports a side of the shower plate 810 and a side of the electrode plate 830. An upper end of the support part 850 is connected to the ceiling surface of the housing 500, and a lower portion of the support part 850 is connected to a side part of the shower plate 810 and a side part of the electrode plate 830. A material of the support part 850 may include a nonmetal.

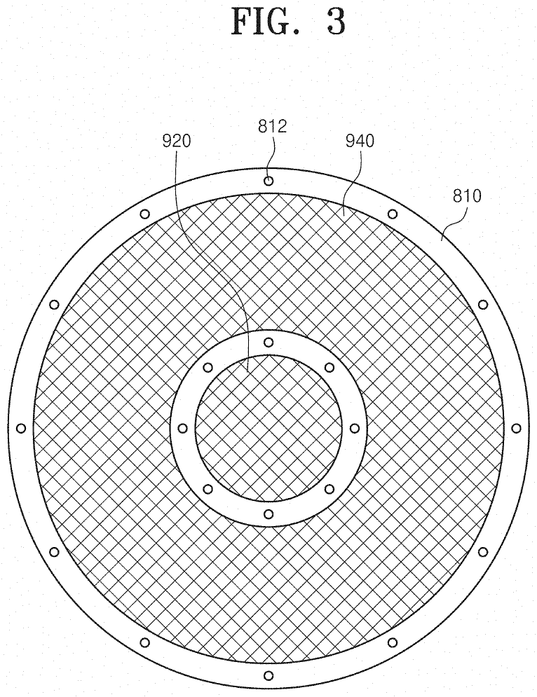

FIG. 3 is a view schematically illustrating a state of the density adjusting member according to an embodiment of FIG. 2, when viewed from a top. Hereinafter, the density adjusting member according to an embodiment of the inventive concept will be described in detail with reference to FIGS. 2 and 3.

The density adjusting member 900 is located in the interior of the housing 500. The density adjusting member 900 may be located on an upper side of the shower plate 810. The density adjusting member 900 may be located between the shower plate 810 and the electrode plate 830. According to an embodiment, the density adjusting member 900 may be bonded and fixed to the upper side of the shower plate 810.

The density adjusting member 900 may adjust a density of the plasma generated in the treatment space 501 by changing the dielectric permittivity. In detail, a density of the electric field generated in the treatment space 501 by the above-described plasma source may be changed as the density adjusting member 900 changes the dielectric permittivity. As the electric field in the treatment space 501 is changed, a degree, by which the process gas supplied to the treatment space 501 is excited by the electric field, may be changed. Accordingly, the density of the plasma generated in the treatment space 501 may be adjusted.

The density adjusting member 900 may include at least one dielectric pad. The dielectric pad may be a dielectric substance having a pad shape of a specific thickness. For example, a material of the dielectric pad may include an aluminum oxide. Furthermore, the material of the dielectric pad may include a metal oxide-based material having a dielectric permittivity that is higher than that of the aluminum oxide. Selectively, the dielectric pad may be formed by mixing the aluminum oxide, and the metal oxide-based material having a dielectric permittivity that is higher than that of the aluminum oxide. For example, the dielectric pad is formed to have various dielectric permittivities by varying a mixing ratio of the aluminum oxide and the metal oxide material.

According to an embodiment, the density adjusting member 900 may include the center pad 920 and the edge pad 940. The center pad 920 may have a substantially circular shape when viewed from the top. A center of the center pad 920 may coincide with a center of the shower plate 810 when viewed from the top. The center pad 920 may be located in a center area (hereinafter, a center area) including the center of the shower plate 810. That is, the center area may have a circular shape. According to an embodiment, the lower surface of the center pad 920 may be bonded to the upper surface of the shower plate 810. As illustrated in FIG. 3, the center pad 920 may be disposed at a location that does not overlap the through-holes 812 formed in the shower plate 810 when viewed from the top. The center pad 920 may have a first dielectric permittivity.

The edge pad 940 may have a substantially ring shape. The edge pad 940 may share the center of the shower plate 810. The edge pad 940 may be located in an edge area (hereinafter, an edge area) of the shower plate 810 that surrounds the center area. That is, the edge area may have a ring shape. The edge area is spaced apart from the center area by a specific distance. Accordingly, the edge pad 940 may be disposed to be spaced apart from the center pad 920 by a specific distance. The through-holes 812 may be located in a space between the edge pad 940 and the center pad 920, which are spaced apart from each other. Furthermore, according to an embodiment, an outer surface of the edge pad 940 may be disposed to be spaced apart from an outer surface of the shower plate 810 by a distance in a direction that faces the center of the shower plate 810. When viewed from the top, the through-holes 812 may be located in the space between the outer surface of the edge pad 940 and the outer surface of the shower plate 810. That is, the through-holes 812 and the edge pad 940 may not overlap each other when viewed from the top.

According to an embodiment, the lower surface of the edge pad 940 may be bonded to the upper surface of the shower plate 810. The edge pad 940 may have a second dielectric permittivity. According to an embodiment, the second dielectric permittivity may be a dielectric permittivity that is lower than the first dielectric permittivity. For example, the center pad 920 may be formed of a material including an aluminum oxide, and the edge pad 940 may be formed as a metal oxide-based material having the dielectric permittivity that is higher than that of the aluminum oxide. However, the inventive concept is not limited thereto, and the dielectric permittivity of the center pad 920 and the dielectric permittivity of the edge pad 940 may be varied by varying a mixing ratio of the aluminum oxide and the metal oxide-based material.

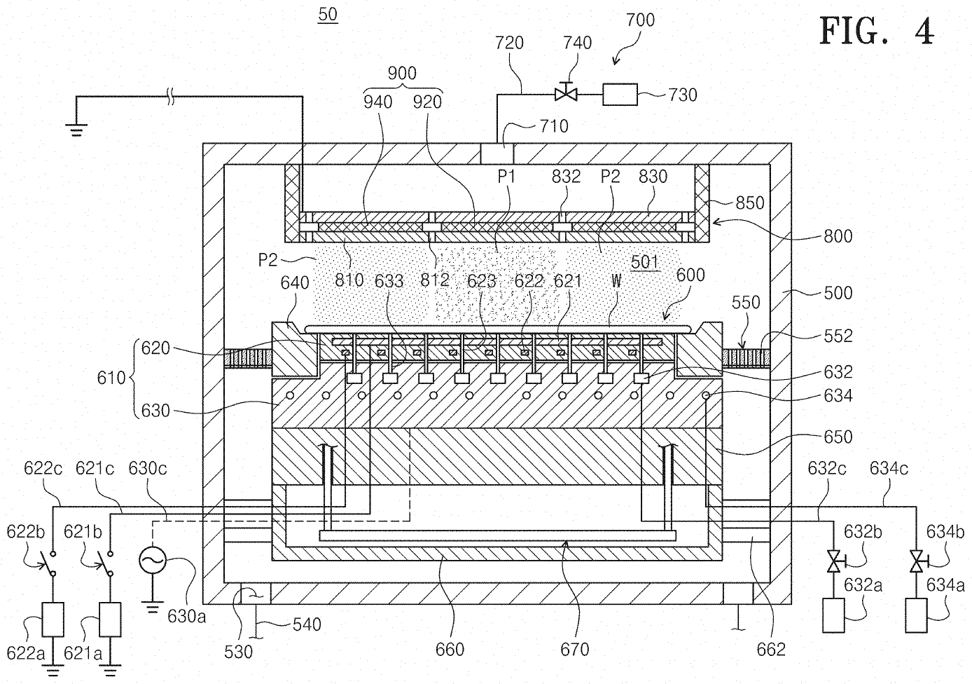

FIG. 4 is a view schematically illustrating a state, in which plasma is generated in the treatment space by the density adjusting member of FIG. 3.

Referring to FIG. 4, first plasma P1 is generated in a central area of the treatment space 501 corresponding to an area, in which the center pad 920 is located, and second plasma P2 is generated in a peripheral area of the treatment space 501 corresponding to an area, in which the edge pad 940 is located.

As described above, the center pad 920 may have the first dielectric permittivity, and the edge pad 940 may have the second dielectric permittivity that is lower than the first dielectric permittivity. The center pad 920 may have a dielectric permittivity that is higher than that of the edge pad 940. As the dielectric permittivity increases, an electric field generated around a dielectric body is significantly offset by an electric bipolar moment. That is, the dielectric permittivity of the dielectric body increases, the electric field may be shielded more by the electric body. Accordingly, a density of the electric field generated in the central area of the treatment space 501 corresponding to the area, in which the center pad 920 is located, may be lower than a density of the electric field generated in the peripheral area of the treatment space 501 corresponding to the area, in which the edge pad 940 is located. Consequently, the first plasma P1 may have a density or an intensity that is lower than that of the second plasma P2.

In general, in a device that generates plasma in a CCP or ICP scheme, the thin film formed in the central area of the substrate is etched more than the thin film formed in the peripheral area of the substrate. A difference between the etching rates for the areas of the substrate occurs due to various factors, such as flows of gases in the treatment space, a uniformity of the supplied process gas in the treatment space, a location of the supplied process gas, and a uniformity of the plasma in the treatment space.

Accordingly, according to an embodiment of the inventive concept, the difference between the etching rate in the central area of the substrate “W” and the etching rate in the peripheral area of the substrate “W” may be minimized by disposing the center pad 920 having a relatively high dielectric permittivity on an upper side corresponding to the central area including the center of the substrate “W” having a relatively high etching rate. Accordingly, when the substrate “W” is plasma-treated, the treatment uniformity of the substrate “W” may be efficiently maintained.

Although it has been described as an example in the above-described embodiment of the inventive concept that the first dielectric permittivity is higher than the second dielectric permittivity, the inventive concept is not limited thereto. The first dielectric permittivity may be lower than the second dielectric permittivity. Furthermore, the first dielectric permittivity may be the same as the second dielectric permittivity. That is, a density of the electric field in the treatment space 501 may be varied for the areas of the treatment space 501 by variously changing the dielectric permittivity of the dielectric pad.

Hereinafter, the density adjusting member according to another embodiment of the inventive concept will be described in detail. Except for additionally described cases, the density adjusting member, which will be described below, has configurations that are almost the same as or similar to the configurations of the above-described density adjusting member, and thus a description of the repeated configurations will be omitted.

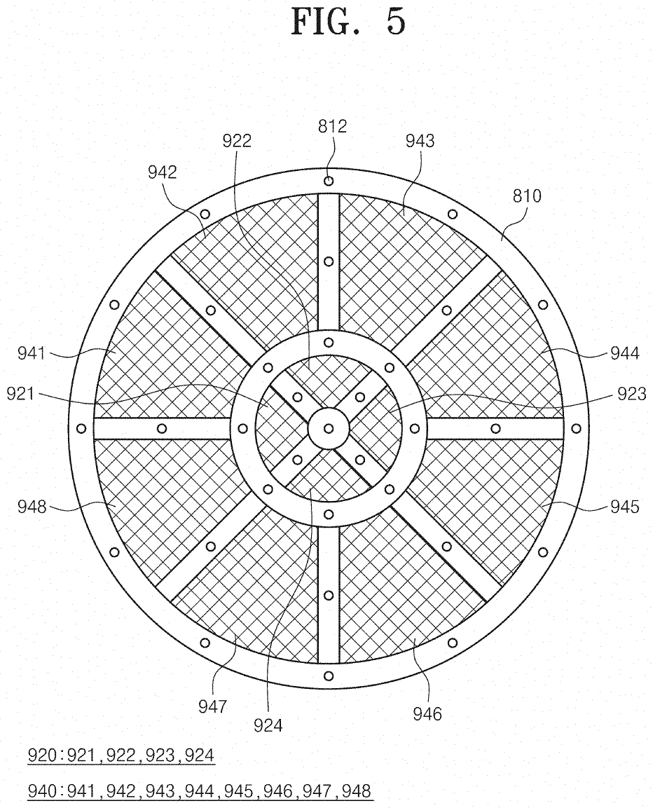

FIG. 5 is a view schematically illustrating a state of the density adjusting member according to another embodiment of FIG. 2, when viewed from the top.

Referring to FIG. 5, a plurality of center pads 920 according to an embodiment may be provided. For example, the center pads 920 may include a first center pad 921, a second center pad 922, a third center pad 923, and a fourth center pad 924.

The first center pad 921, the second center pad 922, the third center pad 923, and the fourth center pad 924 may be combined to have a substantially circular shape when viewed from the top. The center pads 921, 922, 923, and 924 may have the same shape. Furthermore, the center pads 921, 922, 923, and 924 may have the same cross-sectional area.

However, the inventive concept is not limited thereto, and the center pads 921, 922, 923, and 924 may have different shapes and different cross-sectional areas. Furthermore, the number of center pads 921, 922, 923, and 924 illustrated in FIG. 5 are merely described to be four for convenience of description, but the number of center pads 920 according to an embodiment may be two, three, or five.

The first center pad 921, the second center pad 922, the third center pad 923, and the fourth center pad 924 may be disposed to be spaced apart from each other by a specific distance. The through-holes 812 may be located in the spaces between the spaced center pads 921, 922, 923, and 924. The center pads 921, 922, 923, and 924 may have different dielectric permittivities. Selectively, some of the center pads 921, 922, 923, and 924 may have the same dielectric permittivity, and others may have different dielectric permittivities. Selectively, the center pads 921, 922, 923, and 924 may have the same dielectric permittivity.

A plurality of edge pads 940 according to an embodiment may be provided. For example, the edge pads 940 may include first to eighth edge pads 941 to 948.

The edge pads 941 to 948 may be combined to have a substantially ring shape when viewed from the top. The edge pads 941 to 948 may have the same shape and the same cross-sectional area. For example, the edge pads 941 to 948 may have a substantially fan shape when viewed from the top. However, the inventive concept is not limited thereto, and the edge pads 941 to 948 may have different shapes and cross-sectional areas. Unlike the illustration of FIG. 5, the number of edge pads may be variously changed according to a requirement condition of the process or a requirement condition of the user.

The edge pads 941 to 948 may be spaced apart from each other by a specific distance. The through-holes 812 may be located in the spaces between the spaced edge pads 941 to 948. The edge pads 941 to 948 may have different dielectric permittivities. Selectively, some of the edge pads 941 to 948 may have the same dielectric permittivity, and others may have different dielectric permittivities. Selectively, the edge pads 941 to 948 may have the same dielectric permittivity.

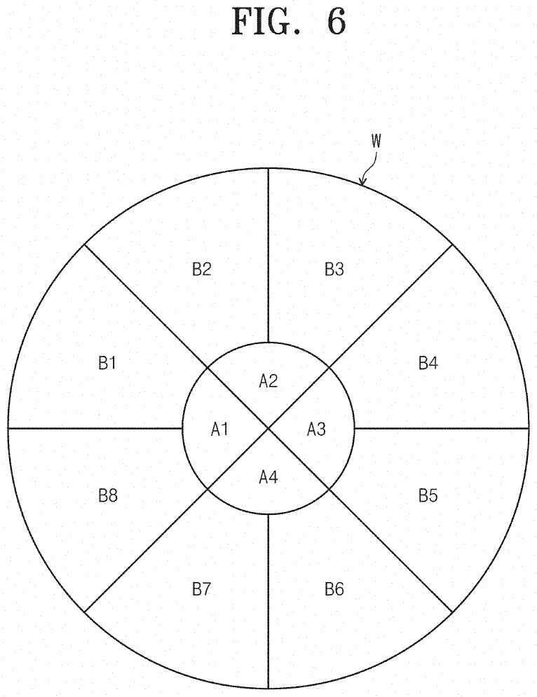

FIG. 6 is a view schematically illustrating a state of the substrate when viewed from the top. The entire area of the substrate “W” illustrated in FIG. 6 may be divided into a central area including a center of the substrate “W” and a peripheral area that surrounds the central area of the substrate “W”. The central area of the substrate “W” includes a first central area A1, a second central area A2, a third central area A3, and a fourth central area A4. The peripheral area of the substrate “W” may include first to eighth peripheral areas B1 to B8.

The first central area A1 overlaps an area, in which the first center pad 921 is located, when viewed from the top. Furthermore, the second central area A2 overlaps an area, in which the second center pad 922 is located, when viewed from the top. Furthermore, the third central area A3 overlaps an area, in which the third center pad 923 is located, when viewed from the top. Furthermore, the fourth central area A4 overlaps an area, in which the fourth center pad 924 is located, when viewed from the top.

The first peripheral area B1 overlaps an area, in which the first edge pad 941 is located, when viewed from the top. Furthermore, the second peripheral area B2 overlaps an area, in which the second edge pad 942 is located, when viewed from the top, the third peripheral area B3 overlaps an area, in which the third edge pad 943 is located, the fourth peripheral area B4 overlaps an area, in which the fourth edge pad 944 is located, the fifth peripheral area B5 overlaps an area, in which the fifth edge pad 945 is located, the sixth peripheral area B6 overlaps an area, in which the sixth edge pad 946 is located, the seventh peripheral area B7 overlaps an area, in which the seventh edge pad 947 is located, and the eighth peripheral area B8 overlaps an area, in which the eighth edge pad 948 is located.

For example, when it is assumed that the first center pad 921 has a first dielectric permittivity, the second center pad 922 has a second dielectric permittivity, the third center pad 923 has a third dielectric permittivity, the fourth center pad 924 has a fourth dielectric permittivity, the first dielectric permittivity is higher than the second dielectric permittivity, the third dielectric permittivity, and the fourth dielectric permittivity, the second dielectric permittivity is higher than the third dielectric permittivity and the fourth dielectric permittivity, and the third dielectric permittivity is higher than the fourth dielectric permittivity, an etching rate of the first central area Al may be lower than that of the second central area A2. Furthermore, the etching rate of the second central area A2 may be lower than that of the third central area A3. Furthermore, the etching rate of the third central area A3 may be lower than that of the fourth central area A4. This mechanism also is the same or similar in the first to eighth peripheral areas.

According to the above-described embodiment of the inventive concept, the areas of the treatment space 501 may be precisely divided by disposing the plurality of center pads 920 and the plurality of edge pads 940 on the shower plate 810 whereby densities of the electric fields generated for the areas of the treatment space 501 may be adjusted more precisely. Accordingly, the etching rates for the areas of the substrate “W” may be adjusted more precisely.

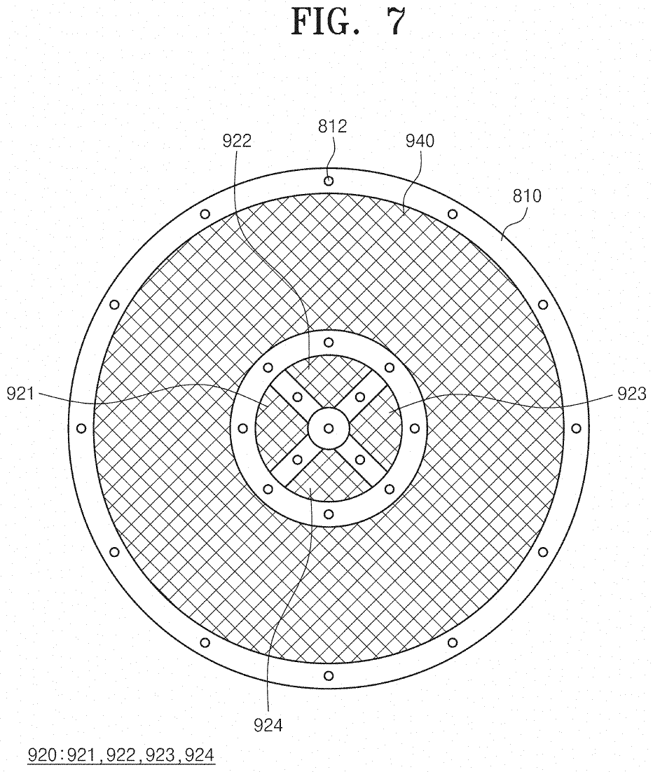

FIG. 7 is a view schematically illustrating a modification of the density adjusting member of FIG. 5. Referring to FIG. 7, the plurality of edge pads 940 may not be disposed in the edge area of the shower plate 810. That is, the edge pad 940 according to an embodiment may have a continuous ring shape. In contrast, the plurality of edge pads 940 may be disposed in the edge area of the shower plate 810, and the center pads 920 may be disposed in the center area of the shower plate 810 while having a circular shape.

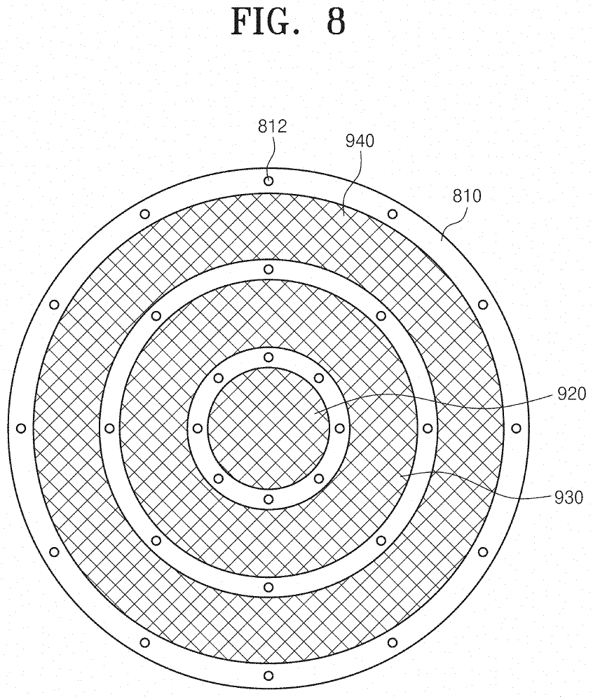

FIG. 8 is a view schematically illustrating a state of a density adjusting member according to another embodiment of FIG. 2, when viewed from a top;

According to an embodiment, the density adjusting member 900 may include the center pad 920, a middle pad 930, and the edge pad 940. The configurations of the center pad 920 are almost the same as or similar to the configurations of the center pad 920 according to the above-described embodiment of the inventive concept, and thus a description thereof will be omitted.

The middle pad 930 may have a substantially ring shape when viewed from the top. The middle pad 930 may share the center of the shower plate 810. The middle pad 930 may be located in a middle area (hereinafter, a middle area) of the shower plate 810 that surrounds the center area. That is, the middle area may have a ring shape. The middle area is spaced apart from the center area by a specific distance. Accordingly, the middle pad 930 may be disposed to be spaced apart from the center pad 920 by a specific distance. The through-holes 812 may be located in a space between the middle pad 930 and the center pad 920, which are spaced apart from each other.

According to an embodiment, the lower surface of the middle pad 930 may be bonded to the upper surface of the shower plate 810. The middle pad 930 may have a second dielectric permittivity. According to an embodiment, the second dielectric permittivity may be a dielectric permittivity that is lower than the first dielectric permittivity.

The edge pad 940 may be located in an edge area (hereinafter, an edge area) of the shower plate 810 that surrounds the middle area. That is, the edge area may have a ring shape. The edge area is spaced apart from the middle area by a specific distance. The through-holes 812 may be located in a space between the edge pad 940 and the middle pad 930, which are spaced apart from each other. The edge pad 940 may have a third dielectric permittivity. The third dielectric permittivity may be a dielectric permittivity that is lower than the second dielectric permittivity.

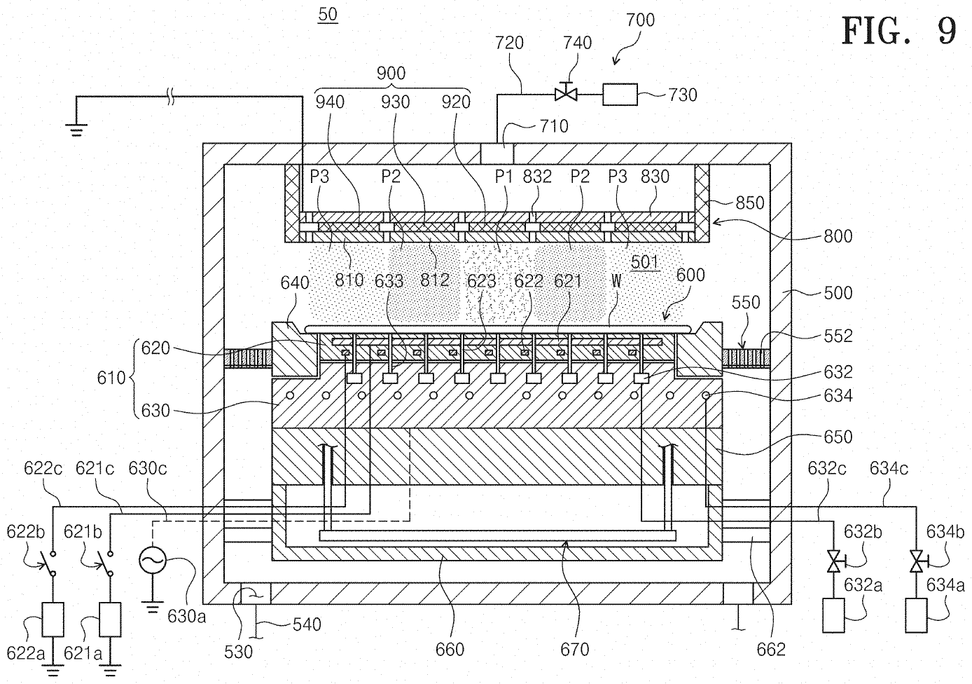

FIG. 9 is a view schematically illustrating a state, in which plasma is generated in the treatment space by the density adjusting member of FIG. 8.

Referring to FIG. 9, first plasma P1 is generated in a central area of the treatment space 501 corresponding to an area, in which the center pad 920 is located, second plasma P2 is generated in a peripheral area of the treatment space 501 corresponding to an area, in which the middle pad 930 is located, and third plasma P3 is generated in a peripheral area of the treatment space 501 corresponding to an area, in which the edge pad 940 is located.

As described above, the center pad 920 may have a dielectric permittivity that is higher than those of the middle pad 930 and the edge pad 940. Furthermore, the middle pad 930 may have a dielectric permittivity that is higher than that of the edge pad 940. Accordingly, a density of the electric field generated in the central area of the treatment space 501 corresponding to the area, in which the center pad 920 is located, may be lower than a density of the electric field generated in the area of the treatment space 501 corresponding to the area, in which the middle pad 930 and the edge pad 940 are located. Furthermore, a density of the electric field generated in the middle area of the treatment space 501 corresponding to the area, in which the middle pad 930 is located, may be lower than a density of the electric field generated in the peripheral area of the treatment space 501 corresponding to the area, in which the edge pad 940 is located. That is, when viewed from the top, the density of the electric field may become higher as it goes from the central area including the center of the treatment space 501 toward the peripheral area of the treatment space 501. Consequently, the first plasma P1 may have a density or an intensity that is lower than that of the second plasma P2. Furthermore, the second plasma P2 may have a density or an intensity that is lower than that of the third plasma P3.

In general, the etching rate of the peripheral area of the substrate is lower than the etching rate of the central area of the substrate. Accordingly, according to an embodiment of the inventive concept, plasma of a uniform intensity may be applied in all of the areas of the substrate “W” by differently adjusting the density (or intensity) of the plasma generated for the areas of the treatment space 501. Accordingly, when the substrate “W” is plasma-treated, the treatment uniformity of the substrate “W” may be efficiently maintained. In particular, according to an embodiment of the inventive concept, the density (or intensity) of the electric field generated in the treatment space 501 may be variously changed for the areas of the treatment space 501 by dividing the areas, in which the pads of different dielectric permittivities are disposed, more precisely whereby the etching rates for the areas of the substrate “W” may be adjusted more uniformly.

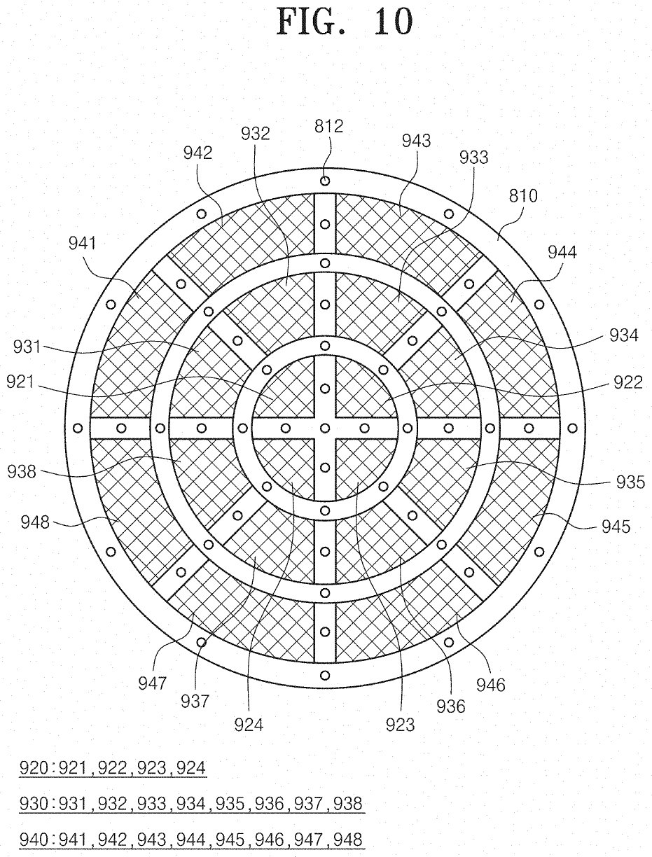

FIG. 10 is a view schematically illustrating a modification of the density adjusting member of FIG. 8.

Referring to FIG. 10, a plurality of middle pads 930 according to an embodiment may be provided. For example, the middle pads 930 may include first to eighth middle pads 931 to 938.

The middle pads 931 to 938 may be combined to have a substantially ring shape when viewed from the top. The middle pads 931 to 938 may have the same shape and the same cross-sectional area. For example, the middle pads 931 to 938 may have a substantially fan shape when viewed from the top. However, the inventive concept is not limited, and the middle pads 931 to 938 may have different shapes and cross-sectional areas. Unlike the illustration of FIG. 5, the number of middle pads may be variously changed according to a requirement condition of the process or a requirement condition of the user.

According to an embodiment of the inventive concept, a substrate may be uniformly treated.

According to an embodiment of the inventive concept, intensities of electric fields generated for areas of a treatment space may be efficiently adjusted.

According to an embodiment of the inventive concept, a substrate may be treated with plasma having a uniform density by adjusting an intensity of an electric field generated in a treatment space.

The effects of the inventive concept are not limited to the above-mentioned effects, and the unmentioned effects can be clearly understood by those skilled in the art to which the inventive concept pertains from the specification and the accompanying drawings.

The above detailed description exemplifies the inventive concept. Furthermore, the above-mentioned contents describe the exemplary embodiment of the inventive concept, and the inventive concept may be used in various other combinations, changes, and environments. That is, the present disclosure can be modified and corrected without departing from the scope of the present disclosure that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to restrict the inventive concept in the disclosed embodiment state. Furthermore, it should be construed that the attached claims include other embodiments.

What is claimed is:

1. A substrate treating apparatus comprising:
a housing having a treatment space, in which a substrate is treated;
a support unit configured to support the substrate in the treatment space;
a shower plate having a through-hole, through which a process gas flows to the treatment space;
a plasma source configured to excite plasma by exciting the process gas supplied to the treatment space; and
a density adjusting member configured to adjust a density of the plasma generated in the treatment space by changing a dielectric permittivity,
wherein the density adjusting member is located on the shower plate.

2. The substrate treating apparatus of claim 1, wherein the plasma source includes an electrode plate located on an upper side of the shower plate, and
wherein the density adjusting member is disposed between the shower plate and the electrode plate.

3. The substrate treating apparatus of claim 2, wherein the density adjusting member includes a plurality of dielectric pads, and
wherein the plurality of dielectric pads are spaced apart from each other while having different permittivities.

4. The substrate treating apparatus of claim 3, wherein the through-hole is located in a space between the plurality of spaced dielectric pads.

5. The substrate treating apparatus of claim 4, wherein the dielectric pad includes a center pad and an edge pad,
wherein the center pad has a first dielectric permittivity, and is located in a circular center area including a center of the shower plate, and
wherein the edge pad has a second dielectric permittivity, and is located in a ring-shaped edge area that surrounds the center area.

6. The substrate treating apparatus of claim 5, wherein the first dielectric permittivity is higher than the second dielectric permittivity.

7. The substrate treating apparatus of claim 5, wherein the first dielectric permittivity is lower than or equal to the second dielectric permittivity.

8. The substrate treating apparatus of claim 5, wherein the dielectric pad includes a plurality of center pads and a plurality of edge pads,
wherein the plurality of center pads are spaced apart from the center area, and
wherein the plurality of edge pads are spaced apart from the edge area.

9. The substrate treating apparatus of claim 8, wherein the plurality of center pads have different dielectric permittivities, and
wherein the plurality of edge pads have different dielectric permittivities.

10. The substrate treating apparatus of claim 4, wherein the dielectric pad is located in any one of a center area including a center of the shower plate, a middle area that surrounds the center area, and an edge area that surround the middle area.

11. The substrate treating apparatus of claim 1, wherein the density adjusting member contacts an upper area of the shower plate.

12. The substrate treating apparatus of claim 2, wherein the electrode plate is grounded or a high-frequency electric power is applied thereto.

13. A substrate treating apparatus comprising:
a housing defining a treatment space, in which a substrate is treated;
a support unit configured to support the substrate in the treatment space;
a gas supply unit configured to supply a process gas;
a plasma source configured to excite the process gas supplied into the treatment space by generating an electric field in the treatment space; and
a density adjusting member configured to differently adjust a density of plasma generated by exciting the process gas according to areas of the treatment space, by shielding the electric field generated in the treatment space.

14. The substrate treating apparatus of claim 13, wherein the density adjusting member includes at least one dielectric pad, and
wherein the dielectric pad shields the electric field generated in at least any one of a center area including a center of the treatment space, a middle area that surrounds the center area, and an edge area that surround the middle area, when viewed from a top.

15. The substrate treating apparatus of claim 14, wherein the dielectric pad includes a center pad, a middle pad, and an edge pad,
wherein the center pad has a first dielectric permittivity, and shields an electric field of the center area,
wherein the middle pad has a second dielectric permittivity, and shields an electric field of the middle area, and
wherein the edge pad has a third dielectric permittivity, and shields an electric field of the edge area.

16. The substrate treating apparatus of claim 15, wherein the first dielectric permittivity, the second dielectric permittivity, and the third dielectric permittivity are different.

17. The substrate treating apparatus of claim 16, wherein the first dielectric permittivity is higher than the second dielectric permittivity and the third dielectric permittivity, and
wherein the second dielectric permittivity is higher than the third dielectric permittivity.

18. The substrate treating apparatus of claim 15, wherein a plurality of center pads are disposed in the center area,
wherein a plurality of middle pads are disposed in the middle area,
wherein a plurality of edge pads are disposed in the edge area, and
wherein the center pads, the middle pads, or the edge pads have different dielectric permittivities.

19. A substrate treating apparatus comprising:
a housing having a treatment space, in which a substrate is treated;
a support unit configured to support the substrate in the treatment space;
a gas supply unit configured to supply a process gas;
a shower plate having a through-hole, through which a process gas flows to the treatment space;
an electrode plate disposed on an upper side of the shower plate, and being grounded or to which high-frequency electric power is applied;
a lower electrode disposed in an interior of the support unit, and being grounded or to which the high-frequency electric power is applied; and
a density adjusting member located between the shower plate and the electrode plate, and configured to adjust a density of plasma generated in the treatment space by shielding an electric field generated in the treatment space by the electrode plate and the lower electrode,
wherein the density adjusting member includes a plurality of dielectric pads,
wherein the plurality of dielectric pads have different dielectric permittivities, and are spaced apart at the upper side of the shower plate, and
wherein the through-hole is located in a space between the plurality of spaced dielectric pads.

20. The substrate treating apparatus of claim 19, wherein the dielectric pad includes at least one center pad and at least one edge pad,
wherein the center pad has a first dielectric permittivity, and is located in a circular center area including a center of the shower plate,
wherein the edge pad has a second dielectric permittivity, and is located in a ring-shaped edge area that surrounds the center area, and
wherein the first dielectric permittivity is higher than the second dielectric permittivity.
